(19) United States
(12) Patent Application Publication
(10) Pub. No.: US 2021/0008750 A1
(43) Pub. Date: Jan. 14, 2021

(54) DISCRETE PIECE MANUFACTURING METHOD

(71) Applicant: LINTEC CORPORATION, Tokyo (JP)

(72) Inventor: Yoshiaki SUGISHITA, Tokyo (JP)

(73) Assignee: LINTEC CORPORATION, Tokyo (JP)

(21) Appl. No.: 17/033,609

(22) Filed: Sep. 25, 2020

Related U.S. Application Data
(63) Continuation of application No. PCT/JP2018/047259, filed on Dec. 21, 2018.

(30) Foreign Application Priority Data
Mar. 29, 2018 (JP) 2018-063681

(51) Int. Cl. B26F 3/00; C09J 7/38; H01L 21/683

(52) U.S. Cl. CPC B26F 3/00; H01L 21/6836; C09J 7/38

(57) ABSTRACT

A discrete piece manufacturing method capable of simplifying a discrete piece manufacturing process includes: a sheet pasting step PC1 of pasting, on a work WF, an adhesive sheet AS containing swell grains SG that swell when predetermined energy IR is applied; a modified part forming step PC2 of, on a subsequent stage of the sheet pasting step PC1, forming modified parts MT in the work WF to form, in the work WF, predefined discrete piece areas WFP each surrounded by the modified parts MT; and an adhesion reducing step PC3 of reducing adhesion of the adhesive sheet AS to the work WF. The adhesion reducing step PC3 includes applying the energy IR to part of the adhesive sheet AS to swell the swell grains SG contained in adhesive sheet parts ASP to which the energy IR has been applied, thereby not only reducing the adhesion area between the adhesive sheet parts ASP and the work WF to reduce the adhesion of the adhesive sheet parts ASP to the work WF but also displacing the predefined discrete piece areas WFP pasted on the adhesive sheet parts ASP to form the discrete pieces CP.

### BACKGROUND OF THE INVENTION

### Field of the Invention

The present invention relates to a discrete piece manufacturing method, and for example, relates to a method for forming many discrete pieces by dividing a work such as a semiconductor wafer into small pieces.

### Description of the Related Art

Examples of a discrete piece forming method include a method that divides a work such as a semiconductor wafer along modified parts formed in the work, into pieces to form discrete pieces. This method requires two steps if a dicing tape pasted on the work has a strong adhesion to the work. One is an expansion step of applying tension to the dicing tape to divide the work into die bond chips (discrete pieces) and the other is an adhesion reducing step of exposing the dicing tape to ultraviolet (energy) radiation.

### SUMMARY OF THE INVENTION

The present invention disclosed and claimed herein, in one aspect thereof, comprises a discrete piece manufacturing method of forming a discrete piece by dividing a work into pieces. The method comprises:

a sheet pasting step of pasting, on the work, an adhesive sheet containing a swell grain that swells when predetermined energy is applied;

a modified part forming step of, on a preceding or subsequent stage of the sheet pasting step, forming a modified part in the work to form, in the work, a predefined discrete piece area surrounded by the modified part or surrounded by the modified part and an outer edge of the work; and

an adhesion reducing step of reducing adhesion of the adhesive sheet to the work, wherein the adhesion reducing step includes applying the energy to part of the adhesive sheet to swell the swell grain contained in an adhesive sheet part to which the energy has been applied, thereby not only reducing an adhesion area between the adhesive sheet part and the work to reduce the adhesion of the adhesive sheet part to the work but also displacing the predefined discrete piece area pasted on the adhesive sheet part to form the discrete piece.

Further scope of applicability of the present invention will become apparent from the detailed description given hereinafter. The detailed description and embodiments are only given as examples though showing preferred embodiments of the present invention, and therefore, from the contents of the following detailed description, changes and modifications of various kinds within the spirits and scope of the invention will become apparent to those skilled in the art.

### BRIEF DESCRIPTION OF THE DRAWINGS

The present invention will be fully understood from the following detailed description and the accompanying drawings. The accompanying drawings only show examples and are not intended to restrict the present invention. In the accompanying drawings:

FIG. 1A is an explanatory view of a discrete piece manufacturing method according to one embodiment;

FIG. 1B is an explanatory view of the discrete piece manufacturing method according to the embodiment;

FIG. 1C is an explanatory view of the discrete piece manufacturing method according to the embodiment;

FIG. 2A is an explanatory view of a modified example;

FIG. 2B is an explanatory view of a modified example; and

FIG. 2C is an explanatory view of a modified example.

### DETAILED DESCRIPTION

An embodiment will be hereinafter described with reference to the drawings.

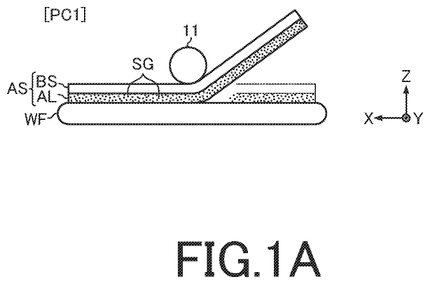

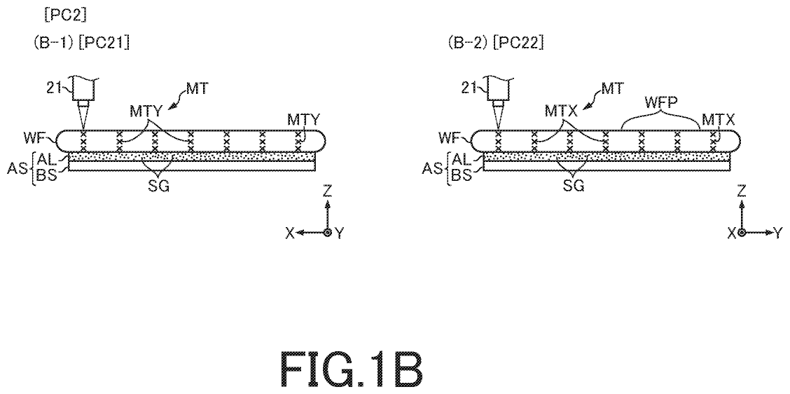

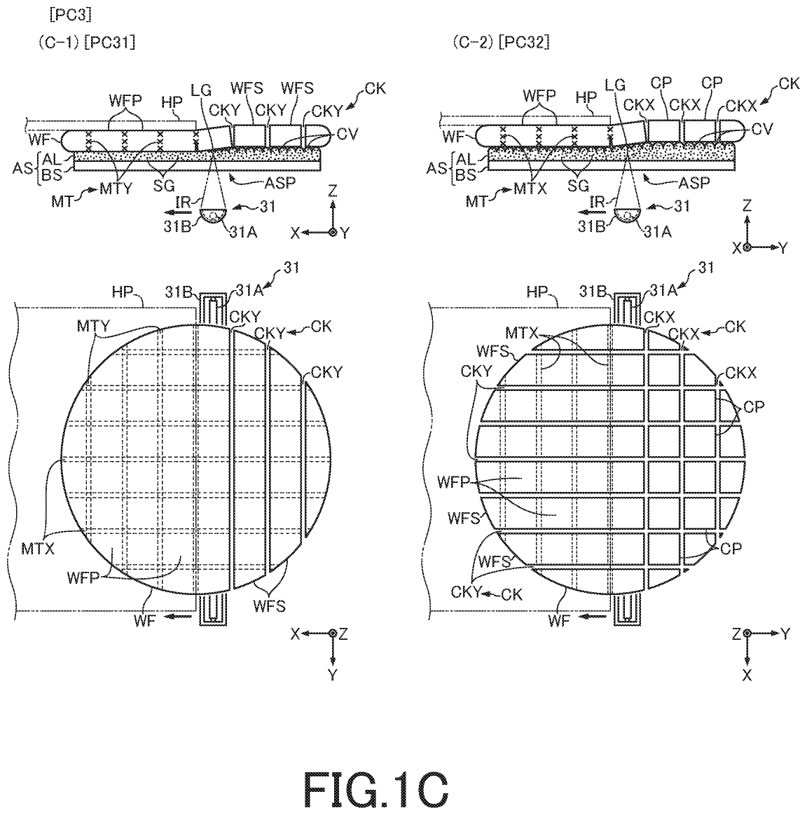

It should be noted that X-axis, Y-axis, and Z-axis in the embodiment are orthogonal to one another, where the X-axis and Y-axis are within a predetermined plane while the Z-axis is orthogonal to the predetermined plane. Further, in the embodiment, FIG. 1A as viewed from the near side in terms of the direction parallel to the Y-axis is used as a reference for direction, and when a direction is mentioned without any designation of a drawing, an “upper” direction means a direction indicated by an arrow along the Z-axis, a “lower” direction means a direction opposite the upper direction, a “left” direction means a direction indicated by an arrow along the X-axis, a “right” direction means a direction opposite the “left” direction, a “front” is direction means a direction toward the near side in FIG. 1A in terms of a direction parallel to the Y-axis, and a “rear” direction means a direction opposite the “front” direction.

A discrete piece manufacturing method divides a semiconductor wafer (hereinafter, also referred to simply as a “wafer”) WF as a work into pieces to form semiconductor chips (hereinafter, also referred to simply as “chips”) CP as discrete pieces, and includes: a sheet pasting step PC1 of pasting, on the wafer WF, an adhesive sheet AS containing swell grains that swell when infrared rays IR as predetermined energy are applied; a modified part forming step PC2 of, on a subsequent stage of the sheet pasting step PC1, forming modified parts MT in the wafer WF to form, in the wafer WF, predefined discrete piece areas WFP each surrounded by the modified parts MT; and an adhesion reducing step PC3 of reducing the adhesion of the adhesive sheet AS to the wafer WF.

In this embodiment, the adhesive sheet AS includes a base BS and an adhesive layer AL, and only the adhesive layer AL contains the swell grains SG.

As illustrated in FIG. 1A, the sheet pasting step PC1 presses the adhesive sheet AS against one surface of the wafer WF with a press roller 11 as a press unit to paste the adhesive sheet AS. In the sheet pasting step PC1, when the adhesive sheet AS is pasted on the wafer WF, one of the press roller 11 and the wafer WF may be moved while the movement of the other is restricted or both of these may be moved. The wafer WF has a predetermined circuit formed on at least one of its one surface and other surface, and in the wafer WF, the adhesive sheet AS may be pasted on the surface having such a circuit or may be pasted on the surface not having the circuit.

As illustrated in FIG. 1B, the modified part forming step PC2 forms the plurality of modified parts MT in the wafer WF with a laser irradiator 21 as a modified part forming unit. FIG. 1B illustrates two steps included in the modified part forming step PC2. Specifically, the modified part forming step PC2 executes: a first modified part forming step PC21 of forming first modified parts MTY extending along the Y-axis direction as a first direction as illustrated in (B-1) in FIG. 1B while moving one of the laser irradiator 21 and the wafer WF in the Y-axis direction and restricting the movement of the other or while moving both of these in the Y-axis direction; and a second modified part forming step PC22 of forming second modified parts MTX extending along the X-axis direction as a second direction intersecting with the Y-axis direction as illustrated in (B-2) in FIG. 1B while moving one of the laser irradiator 21 and the wafer WF in the X-axis direction and restricting the movement of the other or while moving both of these in the X-axis direction. Through these steps, the modified part forming step PC2 forms the predefined discrete piece areas WFP each surrounded by the first modified parts MTY and the second modified parts MTX.

As illustrated in FIG. 1C, the adhesion reducing step PC3 applies infrared rays IR to parts of the adhesive sheet AS with an energy applying unit 31 including a light emitter 31A which emits the infrared rays IR and a condenser plate 31B which condenses the infrared rays IR emitted by the light emitter 31A, to swell the swell grains SG contained in adhesive sheet parts ASP irradiated with the infrared rays IR, thereby not only reducing the adhesion area between the adhesive sheet parts ASP and the wafer WF to reduce the adhesion of the adhesive sheet parts ASP to the wafer WF but also displacing the predefined discrete piece areas WFP pasted on the adhesive sheet parts ASP to form chips CP. When the infrared rays IR are applied to the adhesive layer AL in the adhesion reducing step PC3, one of the energy applying unit 31 and the wafer WF may be moved while the movement of the other is restricted, or both of these may be moved.

FIG. 1C illustrates two steps included in the adhesion reducing step PC3. In this embodiment, the adhesion reducing step PC3 executes: a first adhesion reducing step PC31 of forming a line-shaped application area LG in which an application area of the infrared rays IR extends in a predetermined direction, at a position to which the infrared rays IR are applied, and moving the line-shaped application area LG to make it parallel to the Y-axis direction as illustrated in (C-1) in FIG. 1C; and a second adhesion reducing step PC32 of moving the line-shaped application area LG to make it parallel to the X-axis direction as illustrated in (C-2) in FIG. 1C. In this way, the adhesion reducing step PC3 applies the infrared rays IR to the adhesive layer AL of the adhesive sheet AS pasted on the wafer WF to swell the swell grains SG contained in the adhesive layer AL.

As illustrated in (C-1) in FIG. 1C, in the first adhesion reducing step PC31, the line-shaped application area LG extending along the Y-axis direction is moved from right toward left to successively swell the swell grains SG contained in the adhesive sheet parts ASP to which the infrared rays IR have been applied, thereby forming innumerable convexities CV on the adhesive layer AL. This reduces the adhesion area between the adhesive sheet parts ASP and the wafer WF to reduce the adhesion of the adhesive sheet parts ASP to the wafer WF, and at the same time, raises the wafer WF successively in order from its right parts to left parts to form cracks CKY extending in the Y-axis direction with the first modified parts MTY serving as starting points, so that strip-shaped wafers WFS extending in the Y-axis direction are formed. At this time, the energy applying unit 31 radiates the infrared rays IR such that each of the swell grains SG contained in the adhesive sheet parts ASP irradiated with the infrared rays IR does not completely swell or such that not all of the swell grains SG contained in the adhesive sheet parts ASP irradiated with the infrared rays IR swell.

Next, the energy applying unit 31 is rotated by 90 degrees in an XY plane, and after the line-shaped application area LG formed by the energy applying unit 31 is moved to become parallel to the X-axis direction, the second adhesion reducing step PC32 is executed.

As illustrated in (C-2) in FIG. 1C, in the second adhesion reducing step PC32, the line-shaped application area LG extending along the X-axis direction is moved from the front side toward the rear side of the wafer WF to swell the individual swell grains SG contained in the adhesive sheet parts ASP irradiated with the infrared rays IR, to a greater size one after another or swell a larger number of the swell grains SG contained in the adhesive sheet parts ASP irradiated with the infrared rays IR, so that the innumerable convexities CV formed on the adhesive layer AL are enlarged. This further reduces the adhesion area between the adhesive sheet parts ASP and the wafer WF to further reduce the adhesion of the adhesive sheet parts ASP to the wafer WF, and at the same time, raises the strip-shaped wafers WFS successively in order from the front-side ones to the rear-side ones to form cracks CKX extending in the X-axis direction with the second modified parts MTX serving as starting points, so that the plurality of chips CP are formed owing to the cracks CKX and the previously formed cracks CKY.

It is possible to easily detach the chips CP from the adhesive sheet AS even if the adhesive sheet AS has a strong adhesion to the chips CP (wafer WF) because, owing to the innumerable convexities, the adhesion area of the adhesive sheet AS to the chips CP is reduced, leading to a reduction in its adhesion to the chips CP.

According to the embodiment described above, since the wafer WF is divided into the discrete chips CP in the adhesion reducing step PC3, only one step is required for the work conventionally requiring two steps of a dividing step and an adhesion reducing step, enabling the simplification of the manufacturing steps of the chips CP.

The invention is by no means limited to the above units and processes as long as the above operations, functions, or processes of the units and processes are achievable, still less to the above merely exemplary structures and processes described in the exemplary embodiment. For instance, the sheet pasting step may be any sheet pasting step within the technical scope in is light of the common general technical knowledge at the time of the filing of the application as long as it is a step of pasting, on the work, the adhesive sheet containing the swell grains which swell when predetermined energy is applied (the same applies to other units and steps).

The sheet pasting step PC1 may paste the adhesive sheet AS on the wafer WF by: suction-holding the adhesive sheet AS with a holding member which is supported by an output shaft of a direct-acting motor as a drive device and as the press unit and which is enabled to hold the adhesive sheet AS by a pressure-reducing unit such as a pressure-reducing pump or a vacuum ejector; and pressing the adhesive sheet AS held by the holding member against the wafer WF. The sheet pasting step PC1 may paste the adhesive sheet AS on each of the two surfaces of the wafer WF. If the sheet pasting step PC1 pastes the adhesive sheet AS on each of the two surfaces of the wafer WF, these adhesive sheets AS may be the same or may be different, and one of the adhesive sheets does not necessarily have to contain the swell grains SG.

If the adhesive sheet AS is pasted on the wafer WF beforehand, the discrete piece manufacturing method need not include the sheet pasting step PC1.

The modified part forming step PC2 may precede the sheet pasting step PC1, may form one modified part MT parallel to the X-axis or the Y-axis, may form one modified part MT or more not parallel to the X-axis or the Y-axis, may form a plurality of modified parts MT at uneven intervals, may form a plurality of modified parts MT parallel or not parallel to each other, may form a plurality of modified parts MT not intersecting with each other, may form a plurality of modified parts MT orthogonally or obliquely intersecting with each other, and may form one curved or folded-line shaped modified part MT or more. The predefined discrete piece areas WFP and the chips CP formed by such modified parts MT may be in any shape such as a circular shape, an elliptical shape, or a polygonal shape such as a triangular shape, a quadrangular shape, or a more sided polygonal shape. The modified part forming step PC2 may form one modified part MT or more in one different direction or in each of two different directions or more besides the first and second directions. In this case, the adhesion reducing step PC3 may include one adhesion reducing step or more besides the first and second adhesion reducing steps PC31, PC32.

To form the modified parts MT, the modified part forming unit may embrittle, pulverize, liquefy, or hollow the wafer WF by changing the characteristics, properties, nature, material, composition, structure, size, or the like of the wafer WF by applying laser light, an electromagnetic wave, vibration, heat, chemicals, a chemical substance, or the like. Such modified parts MT may be any as long as they make it possible to divide the work into pieces to form the discrete pieces when the swell grains SG swell.

If the modified parts MT are formed in the wafer WF beforehand, the discrete piece manufacturing method need not include the modified part forming step PC2.

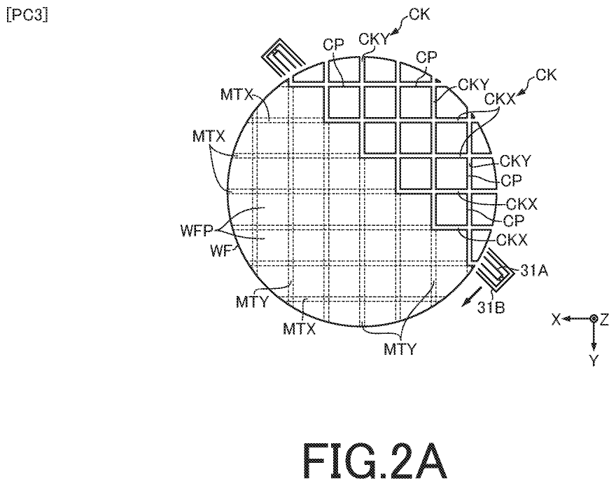

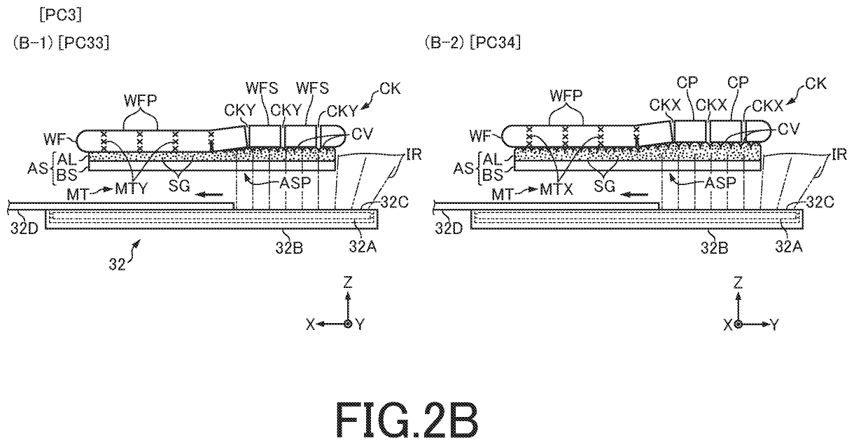

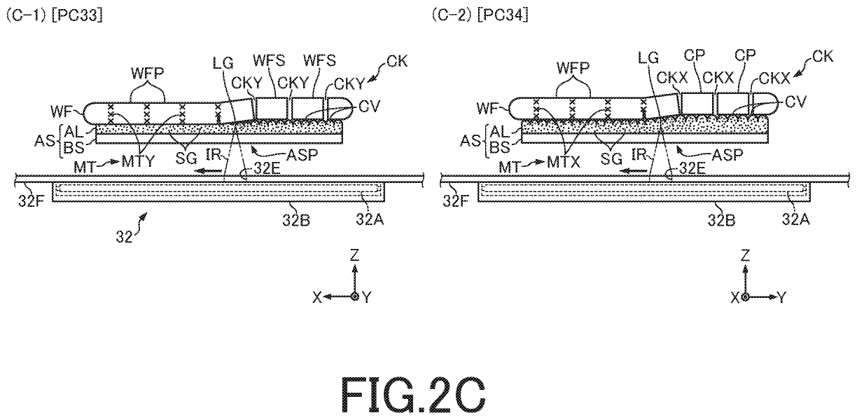

The adhesion reducing step PC3 may move a line-shaped application area LG (not illustrated) obliquely intersecting with the first modified parts MTY or the second modified parts MTX from one end toward the other end of the wafer WF as illustrated in FIG. 2A, to simultaneously form the cracks CKY, CKX starting from the first and second modified parts MTY, MTX, thereby forming the chips CP. In this case, the adhesion reducing step PC3 need not include the second adhesion reducing step PC32. The oblique intersection angle in this case may be any, and for example, may be 1 degree, 5 degrees, 10 degrees, 45 degrees, 60 degrees, 89 degrees, or the like to the X-axis direction. As illustrated in FIG. 2B, the adhesion reducing step PC3 may execute the following first adhesion reducing step PC33 and second adhesion reducing step PC34 by adopting an energy applying unit 32 including a light emitter 32A capable of applying the infrared rays IR to the whole adhesive sheet AS at a time, a reflector plate 32B reflecting the infrared rays IR emitted by the light emitter 32A, and an opening/closing plate 32D capable of opening/closing an opening 32C provided at the top of the reflector plate 32B.

The first adhesion reducing step PC33 forms the cracks CKY one after another in order from the right ones to the left ones as illustrated in (B-1) in FIG. 2B while gradually moving the opening/closing plate 32D, which completely closes the opening 32C at first, from right toward left, thereby forming the strip-shaped wafers WFS extending in the Y-axis direction. Next, after the energy applying unit 32 is rotated by 90 degrees in the XY plane, the second adhesion reducing step PC34 is executed. The second adhesion reducing step PC34 forms the cracks CKX one after another in order from the front ones to the rear ones as illustrated in (B-2) in FIG. 2 while gradually moving the opening/closing plate 32D, which completely closes the opening 32C at first, from the front side toward the rear side, thereby forming the chips CP each surrounded by the cracks CKX and the cracks CKY. In this case, instead of the opening/closing plate 32D, usable is an opening/closing plate 32F including a slit 32E through which the infrared rays IR emitted by the light emitter 32A are applied to form the line-shaped application area LG as illustrated in (C-1) and (C-2) in FIG. 2C. In the slit 32E, a lens that condenses or collimates the infrared rays IR may be provided.

The adhesion reducing step PC3 may, for example, apply the infrared rays IR only to part of the adhesive sheet part ASP corresponding to one section or more at an optional position or more out of the predefined discrete piece areas WFP, thereby not only reducing the adhesion of the part of the adhesive sheet part ASP corresponding to the one section or more to the wafer WF but also displacing the predefined discrete piece areas WSP composed of the one section or more attached to the adhesive sheet part ASP, thereby forming the chips CP.

In the adhesion reducing step PC3, the irradiation duration of the adhesive sheet AS with the infrared rays IR may be decided appropriately in consideration of the characteristics, properties, nature, material, composition, structure, and so on of the swell grains SG. Further, the light emitters 31A, 32A for radiating the infrared rays IR to the adhesive sheet AS each may be a LED (Light Emitting Diode) lamp, a high-pressure mercury lamp, a low-pressure mercury lamp, a metal halide lamp, a xenon lamp, a halogen lamp, or the like, or may be an appropriate combination of these. Further, the energy applying unit may be one that applies, as the predetermined energy, laser light, an electromagnetic wave, vibration, heat, chemicals, a chemical substance, or the like or an appropriate combination of these to the work. The configuration of the energy applying unit may be decided appropriately in consideration of the characteristics, properties, nature, material, combination, structure, and so on of the swell grains SG. If the work is able to transmit the predetermined energy, the energy applying unit may apply the predetermined energy from the work side, from the adhesive sheet AS side, or from both of the work side and the adhesive sheet AS side.

The energy applying units 31, 32 do not necessarily have to include the condenser plate 31B and the reflector plate 32B. A lens that condenses or collimates the infrared rays IR may be provided instead of or in addition to the condenser plate 31B.

For example, the swell grains SG may include not-illustrated first swell grains that are swollen by 80° C. heat as predetermined first energy and not-illustrated second swell grains that are swollen by 100° C. heat as predetermined second energy different from the first energy. In this case, the adhesion reducing step PC3 executes: a first energy applying step of applying 80° C. heat to the adhesive sheet AS to form the cracks CKY starting from the first modified parts MTY; and a second energy applying step of applying 100° C. heat to the adhesive sheet AS to form the cracks CKX starting from the second modified parts MTX to form the chips. In this case, the first energy and the second energy may be heat at any temperature. If the swell grains SG include other swell grains that are swollen by heat at a temperature different from those of the first energy and the second energy, the adhesion reducing step PC3 may further include an adhesion reducing step of applying the heat at this different temperature.

Further, the swell grains SG contained in the adhesive sheet AS may include not-illustrated first swell grains that are swollen by infrared rays as first energy and not-illustrated second swell grains that are swollen by ultraviolet rays as second energy. In this case, the adhesion reducing step PC3 executes: a first energy applying step of applying the infrared rays to form the cracks CKY starting from the first modified parts MTY; and a second energy applying step of applying the ultraviolet rays to form the cracks CKX starting from the second modified parts MTX to form the chips CP. The combination of the first energy and the second energy may be any combination of those out of electromagnetic waves such as infrared rays, ultraviolet rays, visible rays, an acoustic wave, X rays, and gamma rays, hot water, hot air, and so on, depending on the combination of the not-illustrated first and second swell grains contained in the adhesive sheet AS. If the adhesive sheet AS contains other swell grains that are swollen by different energy from the first energy and the second energy, the adhesion reducing step PC3 may further include an adhesion reducing step of applying the different energy.

Further, in the above-described embodiment, the line-shaped application area LG is gradually moved from one end toward the other end of the wafer WF, but to form the cracks CK starting from the modified parts MT, the energy applying unit 31 may be moved such that the line-shaped application area LG is located only at a position where the modified part MT is formed, or the light emitter 31A, which has been kept off, may be driven after the energy applying unit 31 is moved such that the line-shaped application area LG is located only at the position where the modified part MT is formed.

Further, the adhesion reducing step PC3 of the above-described embodiment forms the line-shaped application area LG and applies the infrared rays IR to parts of the adhesive sheet AS, but the adhesion reducing step PC3 may form a dotted application area so that the application area of the infrared rays IR becomes dotted, and apply the infrared rays IR to parts of the adhesive sheet AS, or may form a planar application area corresponding or not corresponding to the planar shape of the predefined discrete piece areas WFP and apply the infrared rays IR to parts of the adhesive sheet AS.

Further, the swell grains SG contained in the adhesive sheet AS may be those that are swollen by an electromagnetic wave such as ultraviolet rays, visible light rays, an acoustic wave, X-rays, or gamma rays, heat of hot water or hot air, or the like as the predetermined energy, and the adhesion reducing step PC3 is not limited as long as it swells the swell grains SG in consideration of their characteristics, properties, nature, material, composition, structure, and so on, thereby capable of not only reducing the adhesion to the work but also dividing the work into the discrete pieces.

At the time of the shift from the first adhesion reducing step PC31 or PC33 to the second adhesion reducing step PC32 or PC34, the wafer WF may be rotated by 90 degrees in the XY plane relative to the energy applying unit 31 or 32 in a stopped state, or the energy applying unit 31 or 32 and the wafer WF may both be rotated relative to each other such that their relative rotation angle in the XY plane becomes 90 degrees.

In the adhesive sheet AS, the swell grains SG may be contained only in the base BS forming the adhesive sheet AS or may be contained in both of the adhesive layer AL and the base BS. The adhesive sheet AS may be one that further includes an intermediate layer between the adhesive layer AL and the base BS, with the swell grains SG contained in at least one or at least two of the intermediate layer, the adhesive layer AL, and the base BS.

The discrete pieces are not limited to the chips CP, and for example, may be strip-shaped wafers WFS, and in this case, the predefined discrete piece areas are each surrounded by the first modified parts MTY and the outer edge of the wafer WF, and the adhesion reducing step PC3 need not include the second adhesion reducing step PC32, PC34.

If the work is formed in the shape of the strip-shaped wafer WFS beforehand, the adhesion reducing step PC3 may form the chips CP only by executing the second adhesion reducing step PC32 or PC34.

As the swell grains SG, grains each having an elastic shell encapsulating a substance, such as isobutane, propane, or pentane, that is easily gasified to swell by heat can be exemplified, and examples of the swell grains SG include, but are not limited to, the thermally foamable grains disclosed in Japanese Patent Application No. 2017-73236, Japanese Patent Application Laid-open No. 2013-159743, Japanese Patent Application Laid-open No. 2012-167151, Japanese Patent Application Laid-open No. 2001-123002, and so on which are explicitly incorporated in the present specification by reference and swell grains disclosed in Japanese Patent Application Laid-open No. 2013-47321, Japanese Patent Application Laid-open No. 2007-254580, Japanese Patent Application Laid-open No. 2011-212528, Japanese Patent Application Laid-open No. 2003-261842, and so on which are explicitly incorporated in the present specification by reference. For example, a foaming agent that generates water, carbonic acid gas, or nitrogen through pyrolysis to exhibit a similar effect to that of the swell grains may be adopted. Also adoptable are those whose shells are swollen by a gas generating agent such as an azo compound which generates gas when exposed to ultraviolet rays, as disclosed in Japanese Patent Application Laid-open No. 2016-53115 and Japanese Patent Application Laid-open No. H07-278333 which are explicitly incorporated in the present specification by reference, or for example, those that are swollen by heating, such as rubber or resin, or baking soda, sodium acid carbonate, baking powder, or the like.

The swell grains SG may be those swollen by the application of an electromagnetic wave such as ultraviolet rays, visible rays, an acoustic wave, X-rays, or gamma rays, or heat of hot water or hot air as the predetermined energy, instead of the infrared rays, and the energy application unit may be selected according to the characteristics, properties, nature, material, composition, structure, and so on of such swell grains SG.

In the wafer WF, it is also acceptable that a circuit is formed on neither of one surface and the other surface.

The discrete piece manufacturing method of the may include a displacement inhibiting step of inhibiting the displacement of parts of the wafer WF which have not yet been displaced in the adhesion reducing step PC3. The displacement inhibiting step places a hold plate HP over the predefined discrete piece areas WFP whose displacement is not intended as illustrated by the two-dot chain lines in FIG. 1C. This can prevent that the predefined discrete piece areas WFP adjacent to the displaced predefined discrete piece areas WFP are displaced together to make it difficult for the modified parts MT to become the cracks CK. Note that such a displacement inhibiting step may place the hold plate HP in contact or in non-contact with the tops of the predefined discrete piece areas WFP whose displacement is not intended. In the displacement inhibiting step, the displacement of the wafer WF which has not yet been displaced may be inhibited by a different method such as by spraying gas or by pulleys and a belt.

To prevent the non-displacement of the predefined discrete piece areas WFP due to the displacement of the adhesive sheet AS when the swell grains SG swell in the adhesion reducing step PC3, a sheet support step of preventing the displacement of the adhesive sheet AS may be executed on a preceding step of the adhesion reducing step PC3. The sheet support step may hold the base BS with a plane, for example, may suction-hold the adhesive sheet AS from the base BS side with a holding plate (holding member) including a holding surface or may paste a plate-shaped member (holding member) such as an iron plate or a glass plate on the base BS side. If the work is unable to transmit the predetermined energy, the holding plate or the plate-shaped member may be one that is able to transmit the predetermined energy, or if the work is able to transmit the predetermined energy, the holding plate or the plate-shaped member may be one that is able to or unable to transmit the predetermined energy. Further, if the adhesive sheet AS has rigidity high enough not to be displaced when the swell grains SG swell, the sheet support step need not be executed or may be executed.

In the discrete piece manufacturing method, a polishing (grinding) step of polishing (grinding) the wafer WF to a predetermined thickness may be executed on a preceding stage of the sheet pasting step PC1, the modified part forming step PC2, or the adhesion reducing step PC3, or on a subsequent stage of the adhesion reducing step PC3. Further, on a subsequent stage of the adhesion reducing step PC3, a detaching step of detaching the chips CP from the adhesive sheet AS may be executed and a bonding step of bonding the chips CP detached from the adhesive sheet AS to another member such as a circuit board or a mount may be executed.

The materials, types, shapes, and so on of the adhesive sheet AS and the work in the present invention are not limited. For example, the adhesive sheet AS may be in a circular shape, an elliptical shape, a polygonal shape such as a triangular shape or a quadrangular shape, or any other shape, and may be of a pressure-sensitive bonding type or a heat-sensitive bonding type. If the adhesive sheet AS is of the heat-sensitive bonding type, it may be bonded by an appropriate method, for example, by an appropriate heating unit for heating the adhesive sheet AS, such as a coil heater or a heating side of a heat pipe. Further, such an adhesive sheet AS may be, for example, a single-layer adhesive sheet having only the adhesive layer AL, an adhesive sheet having an intermediate layer between the base BS and the adhesive layer AL, a three or more-layer adhesive sheet having a cover layer on the upper surface of the base BS, or an adhesive sheet such as what is called a double-faced adhesive sheet in which the base BS can be released from the adhesive layer AL. The double-faced adhesive sheet may be one having one intermediate layer or more, may be a single-layer one or a multilayer one not having an intermediate layer. Further, the work may be, for example, a single item such as food, a resin container, a semiconductor wafer such as a silicon semiconductor wafer or a compound semiconductor wafer, a circuit board, an information recording substrate such as an optical disk, a glass plate, a steel sheet, pottery, a wood board, or a resin, or may be a composite made up of two of these and more. The work may also be a member, an article, or the like of any form. The adhesive sheet AS may be read as one indicating its function or application, and may be, for example, any sheet, film, tape, or the like such as an information entry label, a decoration label, a protect sheet, a dicing tape, a die attach film, a die bonding tape, or a is recording layer forming resin sheet.

The drive device in the above-described embodiment may be an electric machine such as a rotary motor, a direct-acting motor, a linear motor, a uniaxial robot, or a multi joint robot having two joints or three or more joints, an actuator such as an air cylinder, a hydraulic cylinder, a rodless cylinder, or a rotary cylinder, or the like, or may be one in which some of these are directly or indirectly combined.

In the above-described embodiment, in the case where a rotating member such as a roller is used, a drive device that drives the rotation of the rotating member may be provided, and the surface of the rotating member or the rotating member itself may be formed of a deformable member such as rubber or resin, or may be formed of a non-deformable member. In a case where a presser, such as a press unit or a press member such as a press roller or a press head, that presses an object to be pressed is adopted, a member such as a roller, a round bar, a blade member, rubber, resin, or sponge may be adopted or a structure that sprays gaseous substance such as the atmospheric air or gas for pressing may be adopted, instead of or in addition to those exemplified in the above, and the presser may be formed of a deformable member such as rubber or resin or may be formed of a non-deformable member. In a case where a member, such as a support (holding) unit or a support (holding) member, that supports or holds a member to be supported is adopted, the member to be supported may be supported (held) by a gripping unit such as a mechanical chuck or a chuck cylinder, Coulomb force, an adhesive (adhesive sheet, adhesive tape), a tackiness agent (tacky sheet, tacky tape), magnetic force, Bernoulli adsorption, suction/adsorption, a drive device, or the like.

What is claimed is:

1. A discrete piece manufacturing method of forming a discrete piece by dividing a work into pieces, the method comprising:
a sheet pasting step of pasting, on the work, an adhesive sheet containing a swell grain that swells when predetermined energy is applied;
a modified part forming step of, on a preceding or subsequent stage of the sheet pasting step, forming a modified part in the work to form, in the work, a predefined discrete piece area surrounded by the modified part or surrounded by the modified part and an outer edge of the work; and
an adhesion reducing step of reducing adhesion of the adhesive sheet to the work, wherein the adhesion reducing step includes applying the energy to part of the adhesive sheet to swell the swell grain contained in an adhesive sheet part to which the energy has been applied, thereby not only reducing an adhesion area between the adhesive sheet part and the work to reduce the is adhesion of the adhesive sheet part to the work but also displacing the predefined discrete piece area pasted on the adhesive sheet part to form the discrete piece.

2. The method of claim 1,
wherein the modified part forming step comprises:
a first modified part forming step of forming a first modified part extending along a first direction; and
a second modified part forming step of forming a second modified part extending along a second direction intersecting with the first direction, and
wherein the adhesion reducing step comprises:
a first adhesion reducing step of forming a line-shaped application area in which an application area of the energy extends in a predetermined direction, at a position to which the energy is applied, and moving the line-shaped application area to make the line-shaped application area parallel to the first direction; and
a second adhesion reducing step of moving the line-shaped application area to make the line-shaped application area parallel to the second direction.

3. The method of claim 1,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

4. The method of claim 1, further comprising
a displacement inhibiting step of inhibiting the displacement of part, of the work, that has not yet been displaced in the adhesion reducing step.

5. The method of claim 2,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

6. The method of claim 2, further comprising
a displacement inhibiting step of inhibiting the displacement of part, of the work, that has not yet been displaced in the adhesion reducing step.

7. The method of claim 3, further comprising
a displacement inhibiting step of inhibiting the displacement of part, of the work, that has not yet been displaced in the adhesion reducing step.

8. The method of claim 5, further comprising
a displacement inhibiting step of inhibiting the displacement of part, of the work, that has not yet been displaced in the adhesion reducing step.

9. A discrete piece manufacturing method of forming a discrete piece by dividing a work into pieces, the method comprising:
a modified part forming step of forming a modified part in the work having a pre-pasted adhesive sheet containing a swell grain that swells when predetermined energy is applied, to form, in the work, a predefined discrete is piece area surrounded by the modified part or surrounded by the modified part and an outer edge of the work; and
an adhesion reducing step of reducing adhesion of the adhesive sheet to the work, wherein the adhesion reducing step includes applying the energy to part of the adhesive sheet to swell the swell grain contained in an adhesive sheet part to which the energy has been applied, thereby not only reducing an adhesion area between the adhesive sheet part and the work to reduce the adhesion of the adhesive sheet part to the work but also displacing the predefined discrete piece area pasted on the adhesive sheet part to form the discrete piece.

10. The method of claim 9,
wherein the modified part forming step comprises:
a first modified part forming step of forming a first modified part extending along a first direction; and
a second modified part forming step of forming a second modified part extending along a second direction intersecting with the first direction, and
wherein the adhesion reducing step comprises:
a first adhesion reducing step of forming a line-shaped application area in which an application area of the energy extends in a predetermined direction, at a position to which the energy is applied, and moving the line-shaped application area to make the line-shaped application area parallel to the first direction; and
a second adhesion reducing step of moving the line-shaped application area to make the line-shaped application area parallel to the second direction.

11. The method of claim 9,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

12. The method of claim 9, further comprising
a displacement inhibiting step of inhibiting the displacement of part, of the work, that has not yet been displaced in the adhesion reducing step.

13. The method of claim 10,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

14. The method of claim 10, further comprising
a displacement inhibiting step of inhibiting the displacement of part, of the work, that has not yet been displaced in the adhesion reducing step.

15. The method of claim 11, further comprising
a displacement inhibiting step of inhibiting the displacement of part, of the work, that has not yet been displaced in the adhesion reducing step.

16. The method of claim 13, further comprising
a displacement inhibiting step of inhibiting the displacement of part, of the work, that has not yet been displaced in the adhesion reducing step.

17. A discrete piece manufacturing method of forming a discrete piece by dividing a work into pieces, the method comprising:
a sheet pasting step of pasting an adhesive sheet containing a swell grain that swells when predetermined energy is applied, on the work having a modified part and a predefined discrete piece area surrounded by the modified part or surrounded by the modified part and an outer edge of the work; and
an adhesion reducing step of reducing adhesion of the adhesive sheet to the work, wherein the adhesion reducing step includes applying the energy to part of the adhesive sheet to swell the swell grain contained in an adhesive sheet part to which the energy has been applied, thereby not only reducing an adhesion area between the adhesive sheet part and the work to reduce the adhesion of the adhesive sheet part to the work but also displacing the predefined discrete piece area pasted on the adhesive sheet part to form the discrete piece.

18. The method of claim 17,
wherein the modified part comprises:
a first modified part extending along a first direction; and
a second modified part extending along a second direction intersecting with the first direction, and
wherein the adhesion reducing step comprises:
a first adhesion reducing step of forming a line-shaped application area in which an application area of the energy extends in a predetermined direction, at a position to which the energy is applied, and moving the line-shaped application area to make the line-shaped application area parallel to the first direction; and
a second adhesion reducing step of moving the line-shaped application area to make the line-shaped application area parallel to the second direction.

19. The method of claim 17,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

20. The method of claim 17, further comprising
a displacement inhibiting step of inhibiting the displacement of part, of the work, that has not yet been displaced in the adhesion reducing step.

21. The method of claim 18,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

22. The method of claim 18, further comprising
a displacement inhibiting step of inhibiting the displacement of part, of the work, that has not yet been displaced in the adhesion reducing step.

23. The method of claim 19, further comprising
a displacement inhibiting step of inhibiting the displacement of part, of the work, that has not yet been displaced in the adhesion reducing step.

24. The method of claim 21, further comprising
a displacement inhibiting step of inhibiting the displacement of part, of the work, that has not yet been displaced in the adhesion reducing step.

25. A discrete piece manufacturing method of forming a discrete piece by dividing a work into pieces, the method comprising:
an adhesion reducing step of reducing adhesion of an adhesive sheet containing a swell grain that swells when predetermined energy is applied, to the work, the work having the pre-pasted adhesive sheet and having a modified part and a predefined discrete piece area surrounded by the modified part or surrounded by the modified part and an outer edge of the work, wherein the adhesion reducing step includes applying the energy to part of the adhesive sheet to swell the swell grain contained in an adhesive sheet part to which the energy has been applied, thereby not only reducing an adhesion area between the adhesive sheet part and the work to reduce the adhesion of the adhesive sheet part to the work but also displacing the predefined discrete piece area pasted on the adhesive sheet part to form the discrete piece.

26. The method of claim 25,
wherein the modified part comprises:
a first modified part extending along a first direction; and
a second modified part extending along a second direction intersecting with the first direction, and
wherein the adhesion reducing step comprises:
a first adhesion reducing step of forming a line-shaped application area where an application area of the energy extends in a predetermined direction, at a position to which the energy is applied, and moving the line-shaped application area to make the line-shaped application area parallel to the first direction; and
a second adhesion reducing step of moving the line-shaped application area to make the line-shaped application area parallel to the second direction.

27. The method of claim 25,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

28. The method of claim 25, further comprising
a displacement inhibiting step of inhibiting the displacement of part, of the work, that has not yet been displaced in the adhesion reducing step.

29. The method of claim 26,
wherein the swell grain comprises:
a first swell grain that is swollen by predetermined first energy; and
a second swell grain that is swollen by predetermined second energy, and
wherein the adhesion reducing step comprises:
a first energy applying step of applying the first energy to the adhesive sheet; and
a second energy applying step of applying the second energy to the adhesive sheet.

30. The method of claim 26, further comprising
a displacement inhibiting step of inhibiting the displacement of part, of the work, that has not yet been displaced in the adhesion reducing step.

31. The method of claim 27, further comprising
a displacement inhibiting step of inhibiting the displacement of part, of the work, that has not yet been displaced in the adhesion reducing step.

32. The method of claim 29, further comprising
a displacement inhibiting step of inhibiting the displacement of part, of the work, that has not yet been displaced in the adhesion reducing step.
